(19) United States
(12) Patent Application Publication
(10) Pub. No.: US 2013/0328165 A1
(43) Pub. Date: Dec. 12, 2013

(54) MICROFABRICATED MAGNETIC DEVICES AND ASSOCIATED METHODS

(71) Applicant: The Trustees of Dartmouth College, Hanover, NH (US)

(72) Inventors: Daniel V. Harburg, Norwich, VT (US); Charles R. Sullivan, West Lebanon, NH (US); Christopher G. Levey, Thetford Center, VT (US); Jason T. Stauth, Hanover, NH (US)

(21) Appl. No.: 13/911,900

(22) Filed: Jun. 6, 2013

Related U.S. Application Data
(60) Provisional application No. 61/657,186, filed on Jun. 8, 2012.

(51) Int. Cl. H01L 49/02; H01F 5/00

(52) U.S. Cl. CPC H01L 28/10; H01F 5/003
USPC 257/531; 336/221; 438/381

(57) ABSTRACT

A magnetic device includes a semiconductor wafer, a spiral winding, and a magnetic core. The spiral winding forms a plurality of turns and is disposed in a channel of the semiconductor wafer. The magnetic core is disposed at least partially in the channel of the semiconductor wafer and at least partially surrounds the plurality of turns. A width of the spiral winding optionally varies such that a respective width of an edge turn is smaller than a respective width of a middle turn. The channel is formed, for example, by a method including (1) patterning a resist layer on the semiconductor wafer using a mask including angularly extending compensation features, and (2) anistropically etching the semiconductor wafer to form the channel.

### RELATED APPLICATIONS

This application claims benefit of priority to U.S. Provisional Patent Application Ser. No. 61/657,186 filed Jun. 8, 2012, which is incorporated herein by reference.

### GOVERNMENT RIGHTS

This invention was made with government support under contract number DE-AR0000123 awarded by the Department of Energy Advanced Research Project Agency. The government has certain rights in the invention.

### BACKGROUND

Magnetic devices, such as inductors and transformers, are used in many applications, including power conversion applications. For example, inductors are widely used in switching power converters to store energy, and transformers are widely used in power converters to transform a voltage level and/or to provide electrical isolation.

The integration and miniaturization of magnetic devices has become a major focus of the power electronics community as the demand for high-performance, low-volume converters has grown. For example, small and efficient power converters can increase the penetration of energy-saving technologies, such as light emitting diode (LED) lighting, by decreasing system costs and by increasing performance and efficiency. Magnetic devices, however, are generally the largest and most lossy elements in miniature power converters.

One miniature magnetic device that has been proposed is a single-turn V-groove inductor in a silicon substrate, which is well suited for low-voltage, high-current power conversion applications. This inductor can be embedded in thin-film packaging or integrated in the same die as silicon devices, thereby enabling co-packing of the inductor and power switching devices. However, some applications require larger inductance values than those that can be practically fabricated using this single-turn technology. For example, power converters for LED lighting systems often require inductance values above those practically obtainable with a single winding turn.

It is known that large inductance values can be obtained with multiple winding turns. For example, an inductor with four turns will have a significantly larger inductance value than a single-turn inductor, assuming all else is equal. However, increasing the number of winding turns typically increases magnetic device losses.

### SUMMARY

In an embodiment, a magnetic device includes a magnetic core and a planar winding wound through the magnetic core and forming at least first and second turns around a center axis. A width of the planar winding varies between the first and second turns along a radial direction extending away from the center axis, such that a width of the first turn is smaller than a width of the second turn.

In an embodiment, a magnetic device includes a first semiconductor wafer, a first spiral winding, and a magnetic core. The first spiral winding forms a first plurality of turns and is disposed in a first channel of the first semiconductor wafer. The magnetic core is disposed at least partially in the first channel of the first semiconductor wafer and at least partially surrounds the first plurality of turns.

In an embodiment, a method for forming an inductor includes the following steps: (1) patterning a resist layer on a semiconductor wafer using a mask including compensation features extending angularly from a center portion of the mask; (2) anistropically etching the semiconductor wafer to form a trench having sloping sidewalls; (3) disposing a first layer of magnetic material in the trench; (4) forming a spiral multi-turn winding in the trench on the first layer of magnetic material; and (5) disposing a second layer of magnetic material on the spiral multi-turn winding.

In an embodiment, a method for forming an inductor includes the following steps: (1) patterning a first resist layer on a first semiconductor wafer using a first mask including compensation features extending angularly from a center portion of the first mask; (2) anistropically etching the first semiconductor wafer to form a first trench having sloping sidewalls; (3) patterning a second resist layer on a second semiconductor wafer using a second mask including compensation features extending angularly from a center portion of the second mask; (4) anistropically etching the second semiconductor wafer to form a second trench having sloping sidewalls; (5) disposing a first layer of magnetic material in the first trench; (6) disposing a second layer of magnetic material in the second trench; (7) forming a first spiral multi-turn winding in the first trench on the first layer of magnetic material; and (8) joining the first and second semiconductor wafers such that the first and second trenches align.

### BRIEF DESCRIPTION OF THE DRAWINGS

FIG. 1 shows a cross-sectional view of a multi-turn, spiral wound inductor.

FIG. 2 shows a cross-sectional view of a multi-turn, spiral wound inductor with unequal turn widths, according to an embodiment.

FIG. 3 shows multi-turn, spiral wound inductors including magnetic cores with sloping sidewalls, according to an embodiment.

FIG. 4 shows a cutaway perspective view of an electronic device including a silicon substrate and a chip-scale inductor integrated in the substrate, according to an embodiment.

FIG. 5 shows a cross-sectional view of the electronic device of FIG. 4.

FIG. 6 shows a cross-sectional view of a portion of the magnetic core of one embodiment of the electronic device of FIG. 4.

FIG. 7 shows a cross-sectional view of a portion of a prior art magnetic core formed on a substrate.

FIG. 8 shows a cross-sectional view of a portion of the magnetic core of one embodiment of the electronic device of FIG. 4.

FIG. 9 shows a cross-sectional view of an electronic device similar to that of FIG. 4, but where winding turns have varying widths, according to an embodiment.

FIG. 10 shows a method for forming an inductor in a semiconductor substrate, according to an embodiment.

FIG. 11 shows one example of an inductor being formed by the method of FIG. 11.

FIG. 12 shows a mask that is used, for example, to etch trenches in a semiconductor wafer, according to an embodiment.

FIG. 13 shows one possible use of the mask of FIG. 12.

FIGS. 14-17 show top plan views of the inductor of FIG. 11 during certain of the steps of its fabrication.

FIG. 18 shows a cross-sectional view of an electronic device formed of two components, which are joined together and collectively form a magnetic device, according to an embodiment.

FIG. 19 shows the FIG. 18 electronic device, but with the two components separated from each other.

FIG. 20 shows a cross-sectional view of another electronic device formed of two components, which are joined together and collectively form a magnetic device, according to an embodiment.

FIG. 21 shows a cross-sectional view of a magnetic device including a helical winding with unequal turn widths, according to an embodiment.

FIG. 22 shows a cross-sectional view of a magnetic device similar to that of FIG. 21, but including two magnetic cores, according to an embodiment.

### DETAILED DESCRIPTION OF THE EMBODIMENTS

As discussed above, increasing the number of winding turns in a magnetic device typically increases losses in the device. Applicants have discovered, however, that losses associated with multiple turns can be reduced by shaping magnetic flux to reduce or eliminate magnetic field imbalance that typically accompanies multiple turns.

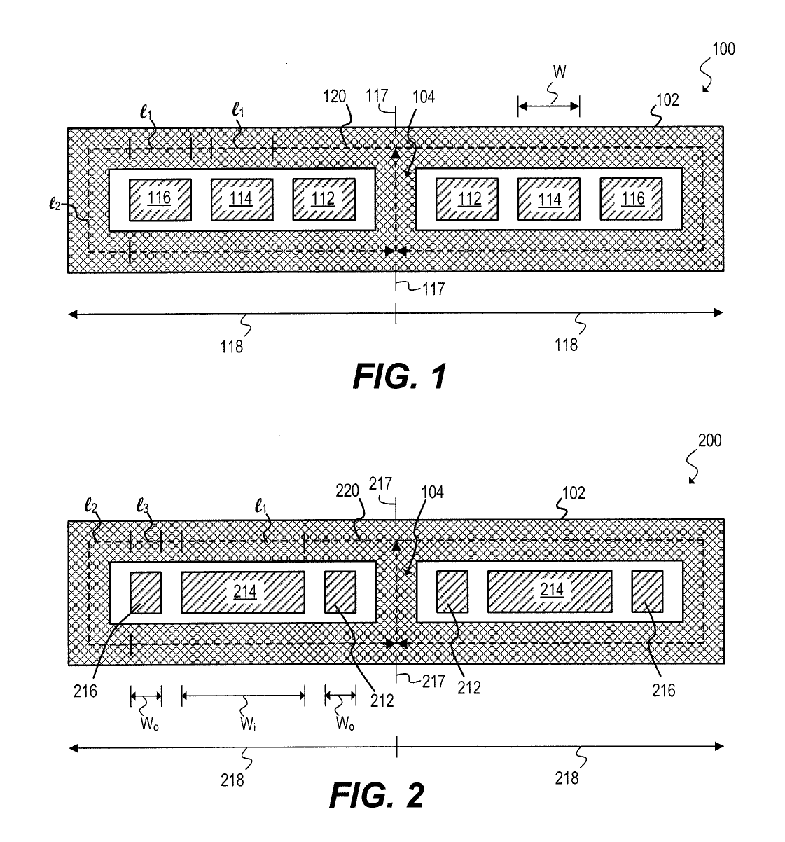

To help appreciate this technique, consider first an inductor where each winding turn has the same width. FIG. 1 shows a cross sectional view of an inductor 100 including a magnetic core 102 having a center post 104. Inductor 100 has, for example, a rectangular shape. A winding having rectangular cross section is spirally wound around center post 104 to form three turns 112, 114, 116 around a center axis 117. The winding is wound through magnetic core 102, which at least partially surrounds each winding turn. Each turn 112, 114, 116 has the same width W in a radial direction 118 extending away from center axis 117. Middle turn 114 is disposed between edge turns 112, 116 in the radial direction.

Large circulating currents are present in edge turns 112, 116 under AC conditions in part due to imbalanced magnetic fields in inductor 100. These circulating currents do not contribute to net current flow through the winding, but instead cause conduction losses in the winding turns. Such losses increase in proportion to frequency and are therefore particularly acute at high frequency operating conditions, which are common in modern power conversion applications. Accordingly, losses in edge turns 112, 116 are greater than losses in middle turn 114.

The imbalance in magnetic fields can be appreciated by considering how magnetomotive force (MMF), which is symbolically shown by dashed lines 120, is dropped along magnetic core 102. MMF is equal to the product of number of turns and current through the turns. Assuming the magnetic field through core 102 is uniform, the portion of MMF dropped in the vicinity of each winding turn 112, 114, 116 is proportional to the length of the turn's edges proximate to magnetic core 102. For example, only the top and bottom edges of middle turn 114 are proximate to core 102, and MMF dropped across middle turn 114 is therefore proportional 2*l₁. l₁ represents the length MMF 120 travels along either the top or bottom edge of turn 114, and is approximately equal to width W. Additional MMF is dropped along the edges of edge turns 112, 116, however, due to a side edge, as well as top and bottom edges, being proximate to magnetic core 102. For example, the MMF dropped across edge turn 116 is 2*l₁+l₂, where l₂ is length MMF 120 travels in the vicinity of the outer side of turn 116. MMF dropped across edge turn 112 is also approximately 2*l₁+l₂. Thus, MMF dropped across edge turns 112, 116 is greater than MMF dropped along middle turn 114, resulting in unbalanced current distribution in winding turns 112, 114, 116 and increased losses in edge turns 112, 116.

Applicants have discovered that magnetic flux can be shaped by reducing the width of edge winding turns, relative to middle winding turns, in a spiral wound multi-turn magnetic device. This flux shaping technique may be applied such that approximately the same amount of MMF is dropped across each winding turn, thereby promoting balanced magnetic fields and corresponding low losses.

For example, FIG. 2 shows an inductor 200, which is similar to inductor 100, and includes a winding spirally wound around center post 104 to form three winding turns 212, 214, 216 around a center axis 217. In certain embodiments, the winding is a planar winding forming three planar winding turns. First edge winding turn 212 is closest to center post 104, second edge winding turn 216 is furthest from center post 104, and middle turn 214 is disposed between first and second edge turns 212, 216, in a radial direction 218 extending from center axis 217. In contrast to inductor 100 (FIG. 1), respective widths of the winding turns vary along radial direction 218. Edge turns 212, 216 each have a width Wₒ, and middle turn 214 has a width Wᵢ. Wᵢ and Wₒ are chosen such that MMF dropped across middle turn 214 is approximately the same as MMF dropped across each edge turn 212, 216. Accordingly, Wₒ is smaller than Wᵢ because a greater portion of the outer edges of turns 216, 212 are proximate to core 102 than the outer edges of turn 214.

MMF 220 dropped across middle turn 214 is 2*l₁, where l₁ is the length MMF 220 travels along either the top or bottom edge of turn 214, and is approximately equal to width Wᵢ. MMF 220 dropped across edge turn 216 is 2*l₃+l₂) where l₂ is length MMF 220 travels in the vicinity of the outer side of turn 216, and l₃ is the length MMF 220 travels along either the top or bottom edge of turn 216, which is approximately equal to Wₒ. In this particular example, l₂ is 1.5 times l₁. Wᵢ is therefore selected to be four times Wₒ to cause MMF dropped across middle turn 214 to be approximately equal to MMF dropped across edge turns 216 and 212. It can be shown that with this relationship between Wᵢ and Wₒ, MMF 220 dropped across middle turn 214 is 8*Wₒ, and MMF dropped across edge turns 212, 216 is also 8*Wₒ. Thus, approximately the same MMF is dropped across each winding turn 212, 214, 216, thereby promoting balanced magnetic fields and corresponding low losses.

This technique of shaping magnetic flux by reducing the width of edge winding turns relative to middle winding turns can be applied to other multi-turn, spiral wound magnetic devices. For example, this technique can be used with different numbers of winding turns, or even with additional windings, such as in a transformer with multiple spiral wound windings. Additionally, this technique can be used with other magnetic core configurations. For example, in some alternate embodiments, the winding is spirally wound around a composite structure including portions of magnetic material and portions of non-magnetic material.

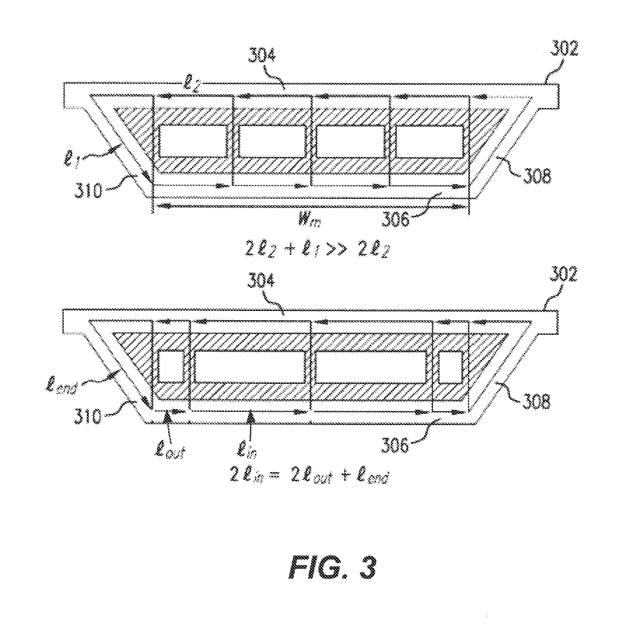

FIG. 3 shows an example of how turn widths can be tuned to achieve equal MMF drop among turns in an inductor including a magnetic core 302 having sloping sidewalls. The top inductor of FIG. 3 has winding turns of equal width, while the bottom inductor of FIG. 3 has winding turns of unequal width. Core 302 includes opposing top and bottom portions 304, 306, and a sloped inner sidewall 308 connecting top and bottom portions 304, 306. A sloped outer sidewall 310, opposite inner sidewall 308, connects top and bottom portions 304, 306. Outer sidewall 310 is sloped in a direction approximately opposite that of inner sidewall 308. FIG. 3 shows cross sections of only half of each inductor for illustrative simplicity—in actuality, another portion symmetrical to the shown portion, is present to the right of inner sidewall 308 of each inductor.

In the top inductor of FIG. 3, MMF dropped across the middle turns is approximately 2*l₂, where l₂ is the length MMF travels along either the top or bottom of each winding turn. MMF dropped across the edge turns, however, is 2*l₂+l₁, where l₁ is the length MMF travels in the vicinity of the sides of the edge turns. Thus, MMF dropped across the edge turns is significantly greater than MMF dropped across the middle turns, resulting in unbalanced current distribution in the winding turns and increased losses in the outer turns.

In the bottom inductor of FIG. 3, in contrast, widths lₒᵤₜ of the edge turns are less than widths lᵢₙ of the middle turns in the radial direction. Specifically, the widths are chosen such that the equation 2*lᵢₙ=2*lₒᵤₜ+l_{end} is satisfied, where l_{end} is the length MMF travels in the vicinity of the sides of the edge turns. Under these conditions, MMF dropped across each middle turn is approximately the same as MMF dropped across each edge turn, thereby promoting balanced magnetic fields and corresponding low losses.

As discussed below, sloping magnetic core sidewalls may be desired in applications where a magnetic device is formed in a semiconductor wafer, such as a silicon wafer. The sloping sidewalls, however, increase the MMF drop disparity between middle and edge turns. Thus, it may be particularly advantageous to reduce the width of edge winding turns relative to middle winding turns in magnetic devices having sloping core sidewalls. In fact, Applicants have conducted simulations showing that reducing the relative width of edge conductors in inductors with sloping core sidewalls may decrease AC losses by around 27%.

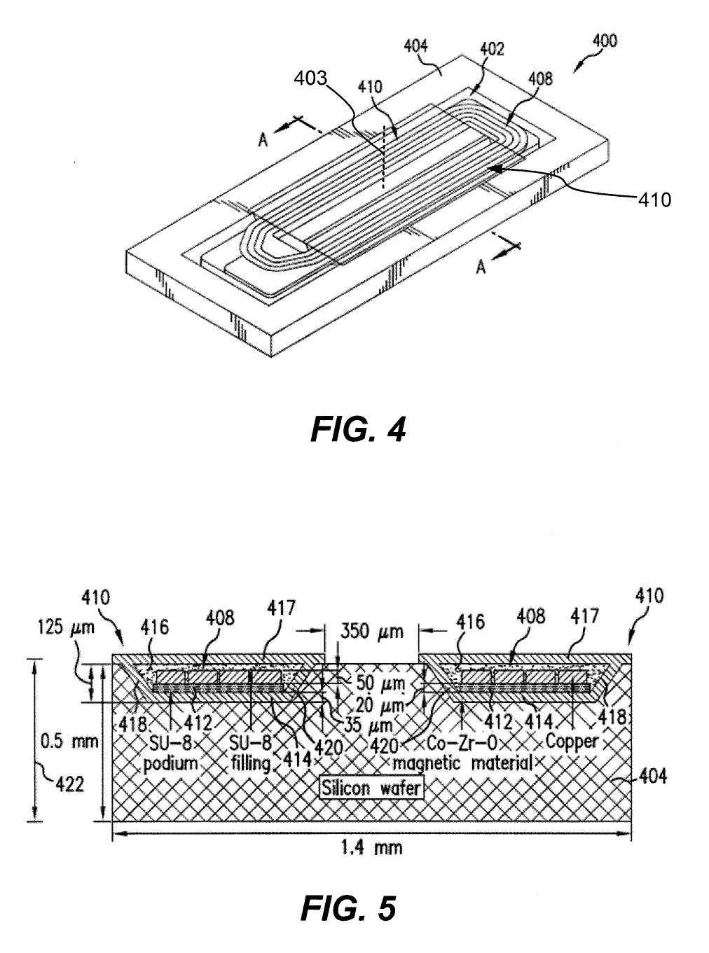

Applicants have also developed miniature magnetic devices which can be integrated in semiconductor wafers and associated methods for forming these devices. For example, FIG. 4 shows a cutaway perspective view of an electronic device 400 including an inductor 402 integrated in a silicon substrate 404. FIG. 5 shows a cross-sectional view of electronic device 400 taken along line A-A of FIG. 4. Inductor 402 is a chip-scale, planar elongated spiral inductor including a winding forming multiple turns around a center axis 403. Accordingly, certain embodiments of inductor 402 are capable of obtaining relatively high inductance values, and may be used, for example, in applications requiring high inductance values, such as in LED lighting applications. Silicon substrate 404 optionally includes one or more electronic components, such as power transistors and/or control logic. Thus, in certain embodiments, inductor 402 and silicon substrate 404 collectively form part or all of a switching power converter, thereby potentially achieving a monolithically integrated power converter.

Inductor 402 is formed in a channel of silicon substrate 404. The channel typically has an elongated shape, such as a rectangular shape, surrounding a center portion of the substrate that is not part of the channel. Inductor 402 includes a copper winding spirally wound around center axis 403 to form winding turns 408. The winding is a planar winding in some embodiments. The winding is wound through two different magnetic cores 410 which are formed, for example, of a thin-film Co—Zr—O magnetic material, as shown in FIG. 5. Each magnetic core 410 includes a bottom portion 414, a top portion 417, and sloping sidewalls 418, 420. Sloping sidewalls 418, 420 act as magnetic vias, connecting bottom portion 414 to top portion 417. The fact that sidewalls 418, 420 are sloping promotes manufacturability of electronic device 400 by providing a surface to sputter magnetic material forming sidewalls 418, 420. If sidewalls 418, 420 were not sloped, it would be difficult to form magnetic vias by sputtering.

A podium 412 formed of insulating material, such as SU-8 epoxy, separates winding turns 408 from bottom portion 414 of each magnetic core 410. Another insulating layer 416, which is also formed of SU-8 epoxy in some embodiments, is formed over winding turns 408 and separates the winding turns from top portion 417 of each magnetic core 410.

It should be appreciated that the dimensions shown in FIG. 5 represent just one embodiment of electronic device 400, and that the device is not limited to having these dimensions. Additionally, device 400 could alternately be formed from materials other than those shown in FIG. 5. For example, silicon wafer 404 could be replaced with another type of semiconductor wafer, the magnetic core could be formed of another type of magnetic material, and/or copper winding turns 408 could be formed of another conductive material, such as gold, silver, aluminum, or doped aluminum.

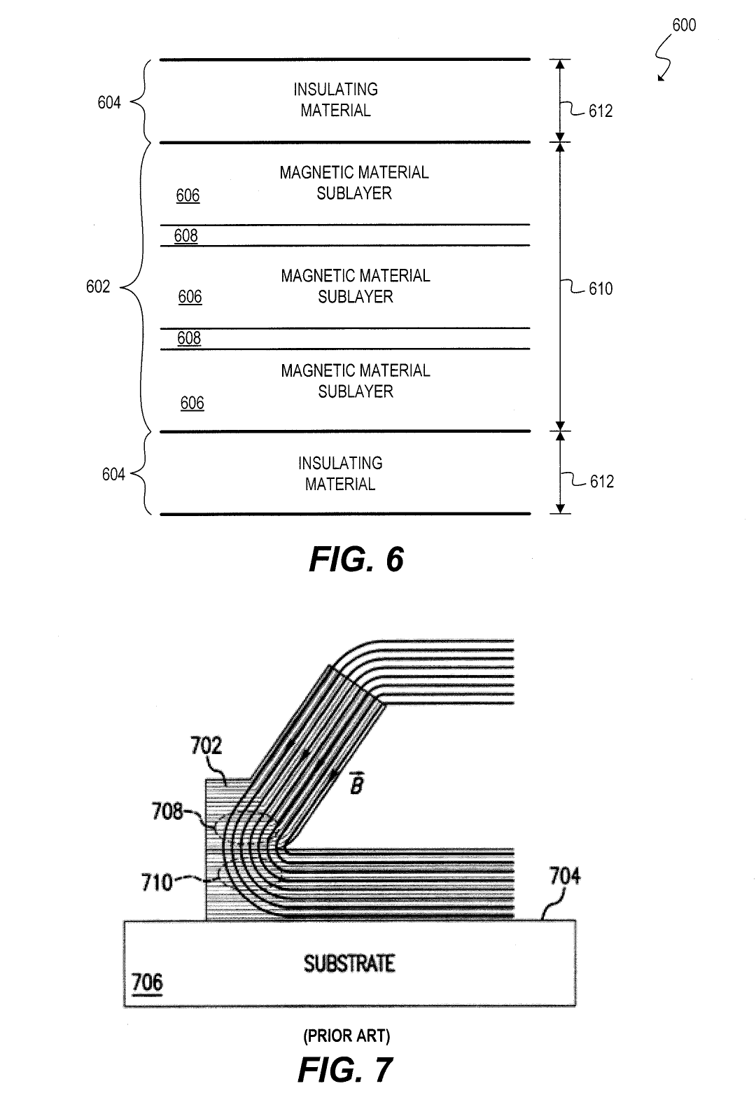

In certain embodiments, at least a portion of each magnetic core 410 is formed of an alternating stack of layers of magnetic material and insulating material, such as alternating layers of Co—Zr—O magnetic material and ZrO₂ ceramic insulating material, to form laminated magnetic layers and thereby reduce eddy current currents and associated losses in the magnetic core. For example, FIG. 6 shows a cross-sectional view of a stack 600 of alternating layers of magnetic material 602 and insulating material 604, which is used to form parts of magnetic cores 410 in certain embodiments of electronic device 400. In some embodiments of stack 600, each magnetic material layer 602 is itself formed of multiple sub-layers 606 of thin magnetic material, such as approximately 20 nm thick layers of Co—Zr—O material that are separated by thin insulating sub-layers 608, such as 4-5 nm thick insulating layers of ZrO₂, to prevent columnar growth when forming layer 602. In certain embodiments, each magnetic material layer 602 has a thickness 610 of about 70 nm, and each insulating layer 604 has a thickness 612 of about 20 nm.

Forming inductor 402 in a channel of substrate 404, instead of on an outer surface of a substrate 404, may offer one or more advantages. For example, forming inductor 402 in a channel of substrate 404 promotes small thickness 422 of device 400 (FIG. 5), by using space inside substrate 404, instead of space above substrate 404. Additionally, forming inductor 402 in substrate 404 promotes precise control of the shape and size of inductor 402, because inductor 402 conforms to shape and size of the channel in substrate 404. It is typically easier to precisely control dimensions of a channel in a semiconductor substrate than dimensions of a structure on an outer surface of the substrate.

Furthermore, forming inductor 402 in substrate 404 promotes low eddy current losses by helping minimize the number of magnetic core layers that are crossed perpendicularly by magnetic flux traveling through the core. See, for example, FIG. 7, which shows a cross-sectional view of a left portion of a conventional magnetic device core 702 formed on an outer surface 704 of a substrate 706. Magnetic flux flowing through this core portion perpendicularly crosses magnetic core lamination layers in both areas 708 and 710, thereby creating significant eddy current losses, since eddy current losses result from magnetic flux flowing perpendicular to magnetic core lamination layers.

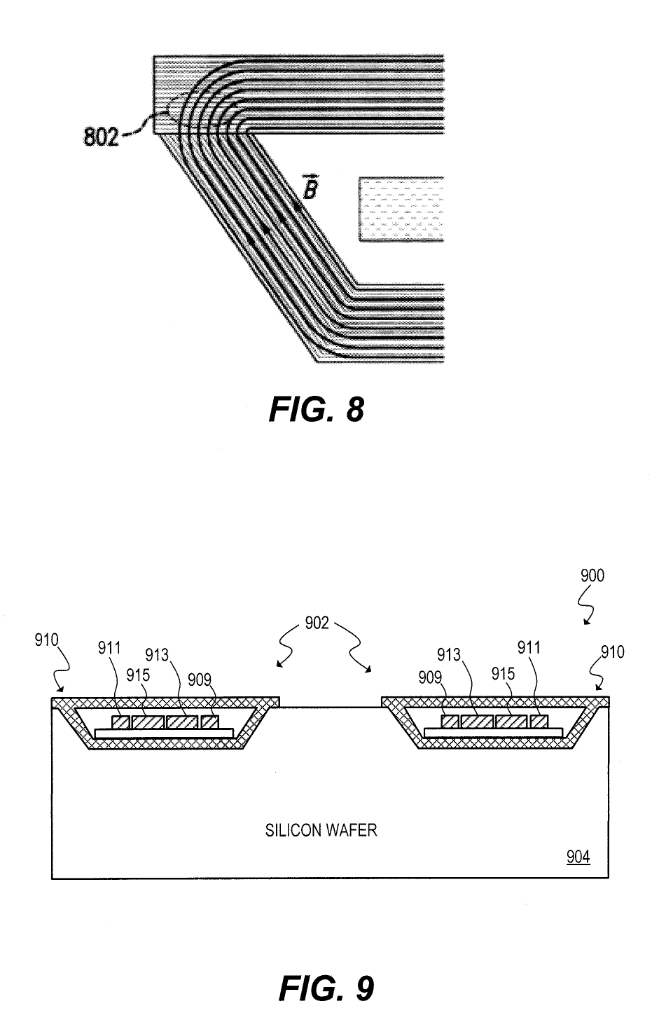

FIG. 8, on the other hand, shows a cross-sectional view of a left portion of an embodiment of magnetic core 410 formed at least partially of laminated magnetic layers, such as discussed above with respect to FIG. 6. Magnetic flux flowing through this core portion perpendicularly crosses magnetic lamination layers in only one area 802. Accordingly, the core portion of FIG. 8 will typically have significantly smaller eddy current losses than the core portion of FIG. 7.

The technique of shaping magnetic flux by reducing the width of middle winding turns relative to edge winding turns is optionally applied to inductor 402 of electronic device 400. For example, FIG. 9 shows a cross-sectional view of an electronic device 900 including an inductor 902 with magnetic cores 910 and formed in a channel of a silicon substrate 904. Inductor 902 is similar to inductor 402 of FIG. 4, but each winding turn of inductor 902 does not have the same width. As shown in FIG. 9, edge winding turns 909, 911 have smaller widths than middle winding turns 913, 915, thereby helping reduce losses associated with magnetic field imbalance.

Discussed below are devices and methods that may be used to fabricate inductors in semiconductor substrates, such as to fabricate inductors 402, 902 in substrates 404, 904 (FIGS. 4 and 9), respectively. It should be appreciated, however, that the devices and methods discussed below are not limited to use in fabricating inductors 402, 902. Additionally, inductors 402, 902 may be fabricated by devices and methods other than those discussed below.

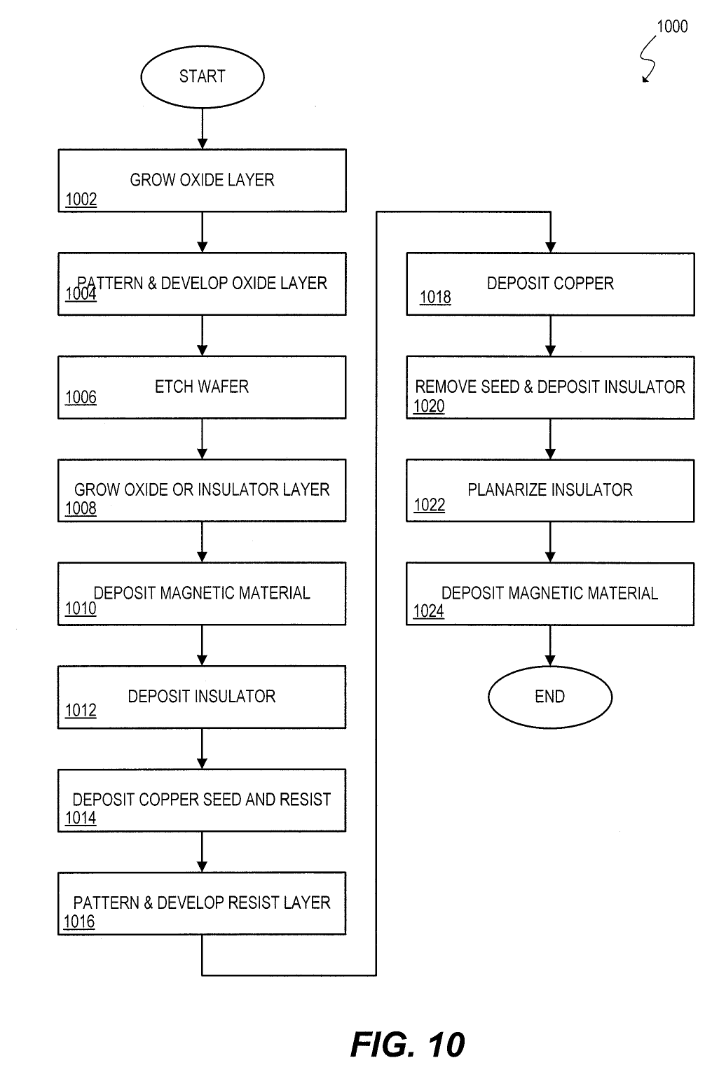

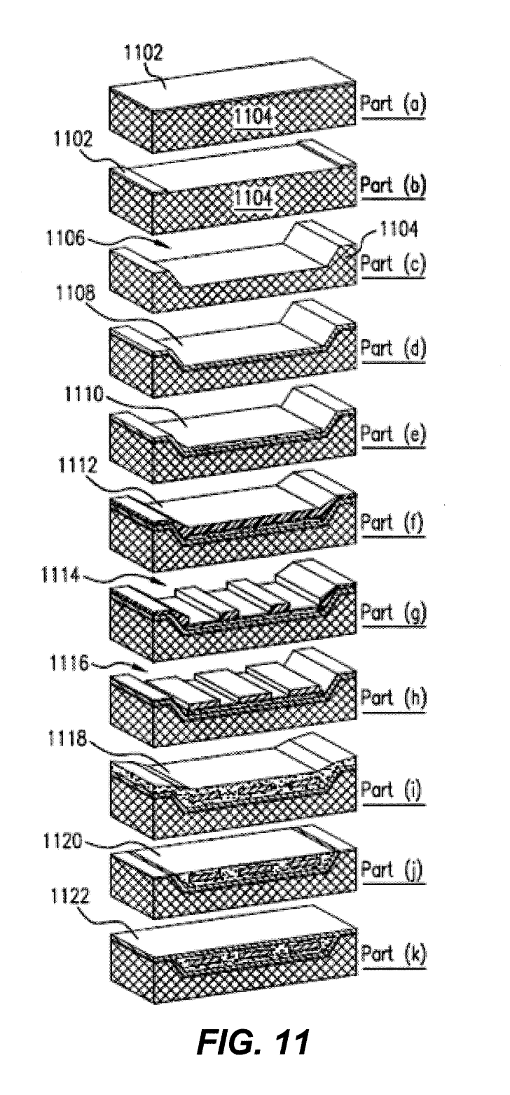

FIG. 10 shows a method 1000 for forming an inductor in a semiconductor substrate, and FIG. 11 shows one example of an inductor being formed by the method of FIG. 10. FIGS. 10 and 11 are best viewed together in the following discussion.

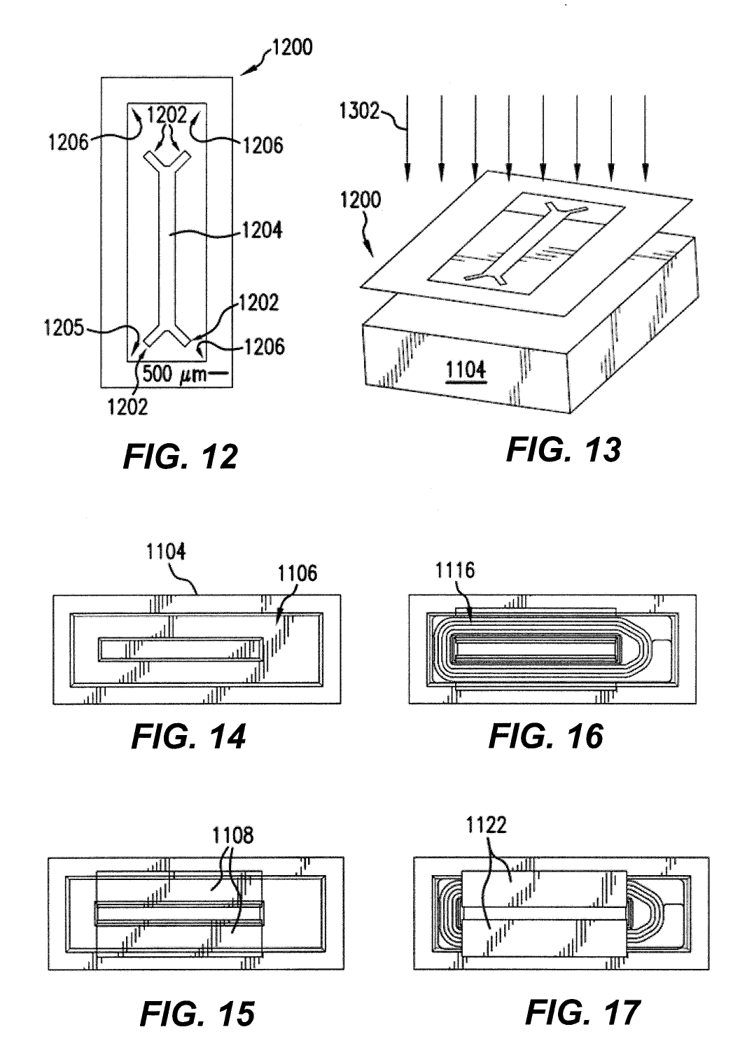

Method 1000 begins with step 1002 of growing an oxide layer on a surface of a semiconductor substrate. An example of step 1002 is growing a 2.5 micron thick oxide layer 1102 on an outer surface of a silicon wafer 1104, as shown in FIG. 11, part (a). The oxide layer grown in step 1002 is patterned in step 1004. An example of step 1004 is depositing Shipley 1813 positive photoresist on an oxidized silicon wafer 1104, exposing the photoresist to ultra violet radiation 1302 at 108 mJ/cm² through mask 1200 (FIG. 12) as shown in FIG. 13, developing the photoresist using Shipley MF 319 developer for one minute, and etching the exposed photoresist in 10% buffered hydrogen fluoride to form the patterned oxide layer shown in FIG. 11, part (b). Mask 1200 includes compensation features 1202 extending angularly from mask center portion 1204, such at approximately 45 degree angles, to promote forming convex corners in remaining portions of wafer 1104. Outer mask corners 1206, in turn, generate concave corners in wafer 1104. Such features of mask 1200 allow etching of 90 degree corners between slopping sidewall channels in wafer 1104. Although mask 1200 is shown in FIG. 12 with a 500 micron scale, its size and proportion can be modified without departing from the scope hereof.

In step 1006 of method 1000, the patterned wafer of step 1004 is etched to form trenches or channels with sloped sidewalls. An example of step 1006 is anisotropically etching wafer 1104 in a 40% weight concentration potassium hydroxide solution for 110 minutes, where the solution is at a temperature 80 degrees Celsius, to form 140 micron deep trenches 1106 in wafer 1104, as shown in FIG. 11, part (c). The wafer is optionally agitated in an ultrasonic bath in step 1006 to improve the surface morphology at the bottom of the trenches. Additionally, in some embodiments of step 1006, the wafer is disposed in a container of etching solution such that long edges of the trenches are normal to the container base. Applicants have discovered that this orientation of the wafer with respect to the container base, agitating in an ultrasonic bath, and/or etching in a solution having a temperature of around 80 degrees Celsius, promote smoothness of the channel, which in turns promotes adhesion magnetic material to the channel.

In step 1008, another oxide layer, or other insulator, is grown or deposited on the semiconductor substrate to insulate the etched portion from magnetic material that is subsequently applied. In step 1010, magnetic material is deposited on the bottoms and sidewalls of the trench etched in step 1006. An example of step 1010 is sputtering a 35 micron thick Co—Zr—O magnetic core 1108 in trench 1106 as shown in FIG. 11, part (d), using a stainless steel shadow mask with Zr and Co targets in an Ar—O mixture. In step 1012, an insulator layer is deposited on the entire device, and the insulating layer is patterned to cover only the trench bottom. An example of step 1012 is depositing and patterning a layer of SU-8 epoxy 1110 with a 70 mJ/cm², 365-405 nm light source, as shown in FIG. 11, part (e).

In step 1014, a copper seed layer is deposited on the device, and negative resist layer is deposited on the copper seed layer. An example of step 1014 is depositing a 660 nm copper seed layer on the device, and then depositing a 60 micron thick BPR-100 negative resist layer 1112, as shown in FIG. 11, part (f). In step 1016, the negative resist layer is patterned and developed to form a negative mold. An example of step 1016 is patterning and developing negative resist layer 1112 to form a negative mold 1114, as shown in FIG. 11, part (g). In step 1018, copper is deposited on the device, and the negative resist layer is stripped to form winding turns. An example of step 1018 is electroplating copper on the device using a cupric sulfate solution with 10 mA/cm² current density, and stripping negative mold 1114, to form 50 micron thick copper winding turns 1116, as shown in FIG. 11, part (h).

In step 1020, copper seed material between winding turns is removed, and another insulating layer is deposited on the device. An example of step 1020 is removing copper seed material between winding turns 1116 by timed etching, depositing a 140 micron thick SU-8 layer 1118 on the device, exposing the SU-8 layer to a 720 mJ/cm² light source, and developing the exposed SU-8 layer, as shown in FIG. 11, part (i). The insulator layer is planarized in step 1022. An example of step 1022 is chemically-mechanically polishing surface 1120 of SU-8 layer 1118, as shown in FIG. 11, part (j). In step 1024, another layer of magnetic material is deposited on the device. An example of step 1024 is sputtering a 35 micron layer 1122 of Co—Zr—O on the device using Z2 and Co targets in an Ar—O mixture, as shown in FIG. 11, part (k).

FIGS. 14-17 show top plan views of the inductor of FIG. 11 during certain of the steps of its fabrication. In particular, FIG. 14 shows the inductor after etching step 1006, where trench 1106 is formed in wafer 1104, and FIG. 15 shows the inductor after magnetic material 1108 is deposited in step 1010. FIG. 16 shows the inductor after forming of winding turns 1116 in step 1018, and FIG. 17 shows the device after applying second magnetic layer 1122 in step 1024.

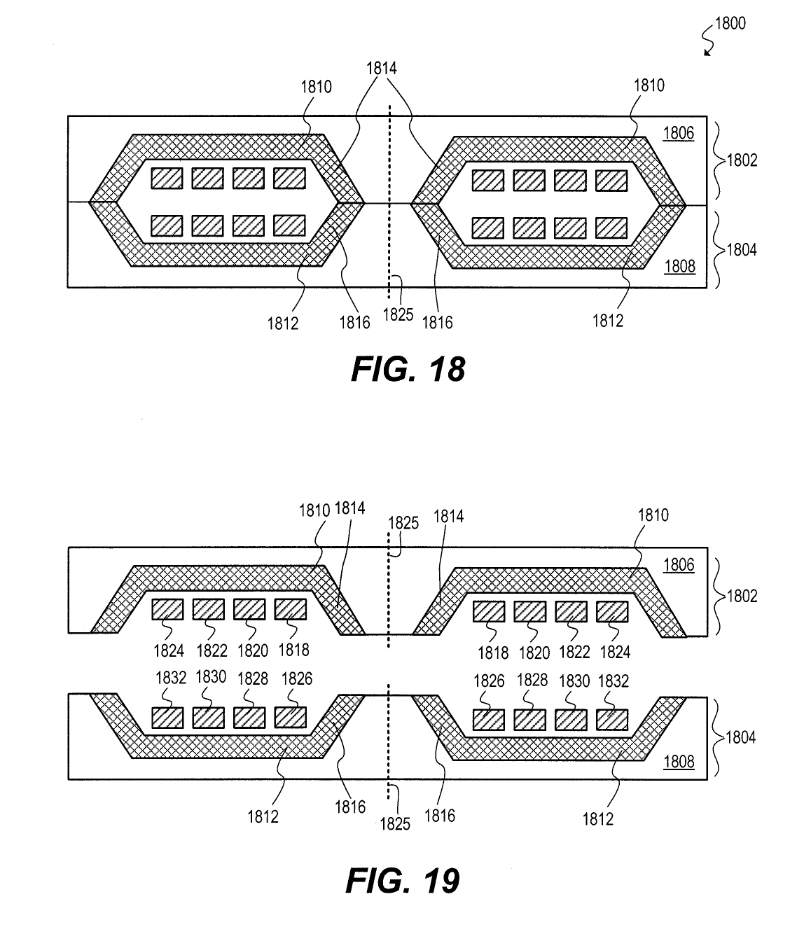

Applicants have also developed miniature magnetic devices from two semiconductor substrates that are joined together. For example, FIG. 18 shows a cross-sectional view of an electronic device 1800 formed of two components 1802, 1804, which are joined together and collectively form a magnetic device, such as an inductor or transformer. FIG. 19 shows components 1802, 1804 separated from each other.

Each component 1802, 1804 includes a respective semiconductor substrate 1806, 1808 with a channel having sloping sidewalls etched therein. One or more layers of magnetic material, such as a Co—Zr—O material, are disposed in each channel to form a magnetic core portion 1810, 1812 in each component. A spiral winding is wound around an inner sloping sidewall 1814, 1816 of each magnetic core portion 1810, 1812, to form a multi-turn winding in each component. In some embodiments, the spiral windings are planar spiral windings. The multi-turn winding of top component 1802 forms winding turns 1818, 1820, 1822, 1824 around a center axis 1825, and the multi-turn winding of bottom component 1804 forms winding turns 1826, 1828, 1830, 1832 around center axis 1825.

In some embodiments, the two windings are electrically isolated such that electronic device 1800 forms a transformer. For example, in these embodiments, the winding of top component 1802 could be used as a primary winding, and the winding of bottom component 1804 could be used as a secondary winding. In other embodiments, the windings are electrically coupled in series or parallel to form an inductor. Although the top and bottom component 1802, 1804 windings are shown as forming the same number of turns, in some alternate embodiments, the two windings form different numbers of turns. Insulating material (not shown), such as SU-8 epoxy, typically separates the winding turns from each other as well as from magnetic core portions 1810, 1812.

Components 1802, 1804 are joined such that their respective channels align, as shown in FIG. 18. Magnetic core portions 1810, 1812 collectively form a common magnetic core. In some alternate embodiments, one or more edge winding turns (e.g., winding turns 1818, 1824, 1826, 1832) have smaller widths than middle winding turns (e.g., winding turns 1820, 1822, 1828, 1830) to reduce losses associated with magnetic field imbalance, in a manner similar to that discussed above with respect to FIGS. 1-3.

In certain embodiments, each component 1802, 1804 is formed using at least some of the methods and devices discussed above with respect to FIGS. 10-17. For example, in some embodiments, each semiconductor substrate 1806, 1808 is patterned using a mask including compensation features, and the substrate is then etched using a potassium hydroxide etching solution, which is optionally maintained at a temperature of around 80 degrees Celsius. Additionally, in some embodiments, each substrate 1806, 1808 is agitated in an ultrasonic bath while etching, and/or each substrate is oriented in a container of etching solution such that long edges of the substrate channels or trenches are normal to the container base during etching.

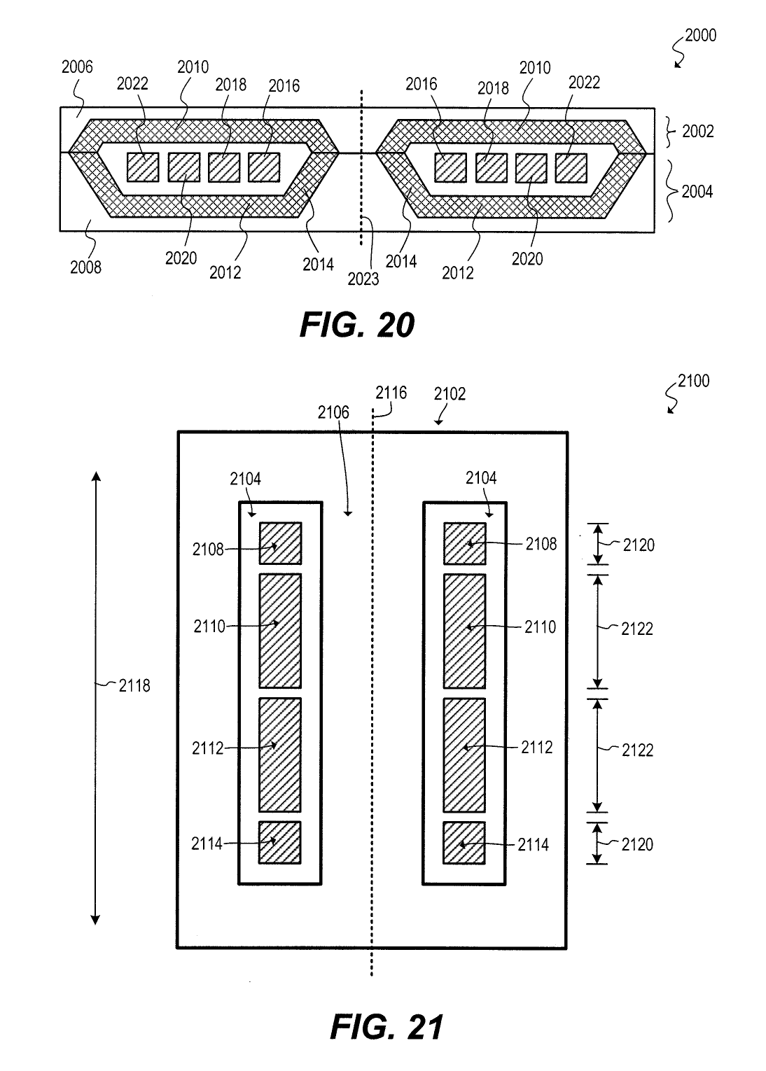

Components 1802, 1804 are typically identical, or nearly identical, to promote manufacturing simplicity. However, multi-substrate magnetic devices can also be formed from two components that are not identical. For example, FIG. 20 shows a cross-sectional view of an electronic device 2000 formed of two components 2002, 2004, which are joined together and collectively form a magnetic device, such as an inductor. Each component 2002, 2004 includes a respective semiconductor substrate 2006, 2008 with a channel having sloping sidewalls etched therein. One or more layers of magnetic material, such as a Co—Zr—O material, are disposed in each channel to form a respective magnetic core portion 2010, 2012.

In contrast to device 1800 (FIG. 18), only bottom component 2004 includes a winding. A spiral winding is wound around an inner sloping sidewall 2014 of magnetic core portion 2012 to form a multi-turn winding in bottom component 2004. In certain embodiments, the spiral winding is a planar spiral winding. The multi-turn winding forms winding turns 2016, 2018, 2020, 2022 around a center axis 2023. Insulating material (not shown), such as SU-8 epoxy, typically separates the winding turns from each other as well as from magnetic core portions 2010, 2012.

Components 2002, 2004 are joined such that their respective channels align. Magnetic core portions 2010, 2012 collectively form a common magnetic core. In some alternate embodiments, edge winding turns 2016, 2022 have smaller widths than middle winding turns 2018, 2020 to reduce losses associated with magnetic field imbalance, in a manner similar to that discussed above with respect to FIGS. 1-3.

In certain embodiments, each component 2002, 2004 is formed using at least some of the methods and devices discussed above with respect to FIGS. 10-17. For example, in some embodiments, top component 2002 is formed using steps 1002-1012 of method 1000 (FIG. 10), and bottom component 2004 is formed using steps 1002-1022 of method 1000.

Applicants have discovered that joining two semiconductor wafers together facilitates forming magnetic cores where magnetic flux perpendicularly crosses relatively few magnetic core laminations, thereby promoting low eddy current losses. For example, in certain embodiments of device 1800 (FIG. 18), magnetic core portions 1810, 1812 are each formed of multiple laminated magnetic layers, similar to that discussed above with respect to FIG. 6, and the laminated layers of the two core portions are substantially aligned. In some embodiments of device 2000 (FIG. 20), magnetic core portions 2010, 2012 are also formed in a similar manner. Substantially aligning magnetic core lamination layers reduces the number of instances where magnetic flux perpendicularly crosses lamination layers, thereby helping to minimize eddy current losses.

The technique of shaping magnetic flux by reducing the width of edge winding turns relative to middle winding turns can further be applied to helical winding magnetic devices. For example, FIG. 21 shows a cross-sectional view of a magnetic device 2100 including a magnetic core 2102 with windows 2104 and a center post 2106. A helical winding is wound through windows 2104 and around a center post 2106 to form winding turns 2108, 2110, 2112, 2114 around a center axis 2116. Winding turns 2108, 2110, 2112, and 2114 are separated from each other along a direction 2118 parallel center axis 2116, and middle winding turns 2110, 2112 are disposed between edge winding turns 2108, 2114 along direction 2118.

A width of the helical winding varies between winding turns along direction 2118. Each edge turn 2108, 2114 has a width 2120 along the direction 2118, and each middle turn 2110, 2112 has a width 2122 along direction 2118. Widths 2120 and 2122 are chosen such that MMF dropped across each middle turn 2110, 2112 is approximately the same as MMF dropped across each edge turn 2108, 2114, in a manner similar to that discussed above with respect to FIG. 2. Thus, widths 2120 will be smaller than widths 2122 because a greater portion of the outer edges of turns 2108, 2114 are proximate to magnetic core 2102 than outer edges of turns 2110, 2112. Such configuration promotes balanced magnetic fields and corresponding low losses, in a manner similar to that discussed above with respect to FIG. 2. In some embodiments, magnetic device 2100 is integrated in a semiconductor wafer.

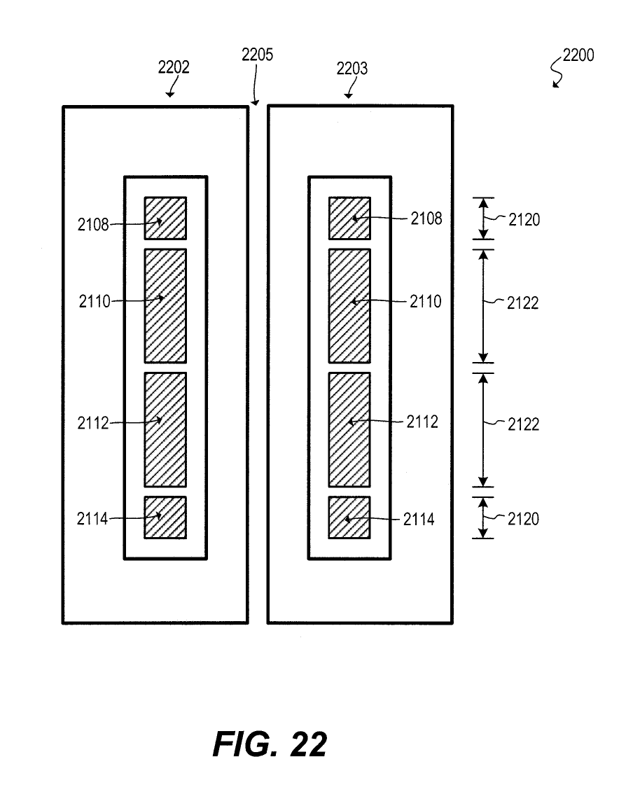

Magnetic device 2100 could be modified such that the helical winding forms a different number of turns, where widths of middle turns are greater than widths of edge turns. Additionally, magnetic core 2102 could have a different configuration. For example, FIG. 22 shows a cross-sectional view of a magnetic device 2200, which is similar to magnetic device 2100 of FIG. 21, but with magnetic core 2102 replaced with two separate magnetic cores 2202, 2203, such that the helical winding is wound around portions of both magnetic cores 2202, 2203. Space 2205 between magnetic cores 2202, 2203 is, for example, occupied by non-magnetic material, such as semiconductor material in embodiments where magnetic device 2200 is integrated in a semiconductor wafer.

### Combinations of Features

Features described above as well as those claimed below may be combined in various ways without departing from the scope hereof. The following examples illustrate some possible combinations:

(A1) A magnetic device may include a magnetic core and a planar winding wound through the magnetic core. The planar winding may form at least first and second turns around a center axis. A width of the planar winding may vary between the first and second turns along a radial direction extending away from the center axis such that a width of the first turn is smaller than a width of the second turn.

(A2) In the magnetic device denoted as (A1), the planar winding may further form a third turn around the center axis, and a width of the third turn may be smaller than a width of the second turn.

(A3) In the magnetic device denoted as (A2), the second turn may be disposed between the first and third turns in the radial direction.

(A4) In any of the magnetic devices denoted as (A1) through (A3), the magnetic core may at least partially surround at least the first and second turns.

(A5) In any of the magnetic devices denoted as (A1) through (A4), the magnetic core may include: (1) opposing top and bottom portions, and (2) opposing inner and outer sidewalls connecting the top and bottom portions.

(A6) In the magnetic device denoted as (A5), the inner and outer sidewalls may slope in opposite directions.

(A7) Any of the magnetic devices denoted as (A1) through (A6) may be integrated in a semiconductor wafer.

(A8) In any of the magnetic devices denoted as (A1) through (A7), the winding may have a rectangular cross section.

(B1) A magnetic device may include a magnetic core and a planar winding wound spirally around at least a portion of the magnetic core. The planar winding may form at least first, second, and third turns around a center axis. The first turn may be closest to the center axis and have a first width in a radial direction extending away from the center axis. The third turn may be furthest from the center axis and may have a third width in the radial direction extending away from the center axis. The second turn may be disposed between the first and second turns and may have a second width in the radial direction extending away from the center axis. Each of the first and third widths may be smaller than the second width.

(C1) A magnetic device may include a first semiconductor wafer and a first spiral winding fanning a first plurality of turns and disposed in a first channel of the first semiconductor wafer. The magnetic device may further include a magnetic core disposed at least partially in the first channel of the first semiconductor wafer and at least partially surrounding the first plurality of turns.

(C2) In the magnetic device denoted as (C1), a width of the first spiral winding may vary between the first plurality of turns such that a width of an edge turn of the first plurality of turns is smaller than a width of a middle turn of the first plurality turns.

(C3) In either of the magnetic devices denoted as (C1) or (C2), the first channel of the first semiconductor wafer may have sloping sidewalls.

(C4) In any of the magnetic devices denoted as (C1) through (C3), the magnetic core may include a Co—Zr—O material.

(C5) In any of the magnetic devices denoted as (C1) through (C4), at least a portion of the magnetic core may include alternating layers of a magnetic material and an insulating material.

(C6) In the magnetic device denoted as (C5), the magnetic material may include Co—Zr—O, and the insulating material may include ZrO₂.

(C7) In any of the magnetic devices denoted as (C1) through (C6), the first semiconductor wafer may include a silicon wafer.

(C8) Any of the magnetic devices denoted as (C1) through (C7) may further include a second semiconductor wafer and a second winding forming a second plurality of turns and disposed in a second channel of the second semiconductor wafer. The first and second semiconductor wafers may be joined such that the first and second channels are aligned.

(C9) In the magnetic device denoted as (C8), the magnetic core may include a first magnetic core portion formed in the first channel and a second magnetic core portion formed in the second channel.

(C10) In magnetic device denoted as (C9), the first magnetic core portion may include a first plurality of laminated magnetic layers, and the second magnetic core portion may include a second plurality of laminated magnetic layers. The second plurality of laminated magnetic layers may be aligned with the first plurality of laminated magnetic layers.

(C11) Any of the magnetic devices denoted as (C1) through (C7) may further include a second semiconductor wafer.

(C12) In the magnetic device denoted as (C11), the magnetic core may include a first magnetic core portion formed in the first channel of the first semiconductor wafer, and a second magnetic core portion formed in a second channel of the second semiconductor wafer. The first and second semiconductor wafers may be joined such that the first and second channels are aligned.

(C13) Any of the magnetic devices denoted as (C1) through (C7) may further include an additional magnetic core disposed at least partially in the first channel of the semiconductor wafer and at least partially surrounding the first plurality of turns.

(D1) A method for forming a trench in a semiconductor wafer may include (1) patterning a resist layer on the semiconductor wafer using a mask including compensation features extending angularly from a center portion of the mask, and (2) anistropically etching the wafer to form a trench having sloping sidewalls.

(D2) In the method denoted as (D1), the step of anistropically etching may include etching the wafer using a potassium hydroxide solution.

(D3) In the method denoted as (D2), the step of anistropically etching may further include agitating the semiconductor wafer in an ultrasonic bath.

(D4) In either of the methods denoted as (D2) or (D3), the step of anistropically etching may include orienting the semiconductor wafer in a container holding the potassium hydroxide solution such that a long edge of the trench is normal to a base of the container.

(D5) In any of the methods denoted as (D2) through (D4), the potassium hydroxide solution may be at a temperature of about 80 degrees Celsius.

(E1) A method for forming an inductor may include (1) forming a trench in a semiconductor wafer according to any one of the methods denoted as (D1) through (D5), (2) disposing a first layer of magnetic material in the trench, (3) forming a spiral multi-turn winding in the trench, and (4) disposing a second layer of magnetic material on the spiral multi-turn winding.

(E2) In the method denoted as (E1), either of the steps of disposing a first layer of magnetic material or disposing a second layer of magnetic material may include alternatively disposing a layer of magnetic material and a layer of insulating material.

(E3) Either of the methods denoted as (E1) or (E2) may further include disposing a first insulating layer on the first layer of magnetic material, before forming the spiral multi-turn winding.

(E4) The method denoted as (E3) may further include disposing a second insulating layer on the spiral multi-turn winding, before disposing the second layer of magnetic material.

(F1) A method for forming an inductor may include (1) forming a first trench in a first semiconductor wafer and a second trench in a second semiconductor wafer, according to any one of the methods denoted as (D1) through (D5), (2) disposing a first layer of magnetic material in the first trench, (3) disposing a second layer of magnetic material in the second trench, (4) forming a first spiral multi-turn winding in the first trench, and (5) joining the first and second semiconductor wafers such that the first and second trenches align.

(F2) The method denoted as (F1) may further include forming a second spiral multi-turn winding in the second trench, before joining the first and second semiconductor wafers.

(F3) The method denoted as (F2) may further include (1) disposing a first layer of insulating material in the first trench, before the step of forming the first spiral multi-turn winding in the first trench, and (2) disposing a second layer of insulating material in the second trench, before the step of farming the second spiral multi-turn winding in the second trench.

(F4) The method denoted as (F3) may further include disposing at least one additional layer of insulating material on at least one of the first and second spiral multi-turn windings, before joining the first and second semiconductor wafers.

(F5) The method denoted as (F1) may further include (1) disposing a first layer of insulating material in the first trench, before the step of forming the first spiral multi-turn winding in the first trench, and (2) disposing at least one additional layer of insulating material on the first spiral multi-turn winding, before joining the first and second semiconductor wafers.

(G1) A magnetic device may include a magnetic core and a helical winding wound around at least a portion of the magnetic core. The helical winding may form at least first and second turns around a center axis. A width of the helical winding may vary between the first and second turns along a direction parallel to the center axis.

(G2) In the magnetic device denoted as (G1), the helical winding may further form a third turn around the center axis, a width of the third turn may be smaller than the width of the second turn, and the second turn may be disposed between the first and third turns along the direction parallel to the center axis.

(G3) In either of the magnetic devices denoted as (G1) or (G2), the magnetic core may include first and second magnetic cores, such that the helical winding is wound around portions of both of the first and second magnetic cores.

(G4) In the Magnetic device denoted as (G3), the two magnetic cores may be separated from each other by non-magnetic material.

(G5) In any of the magnetic devices denoted as (G1) through (G4), the magnetic device may be integrated in a semiconductor wafer.

Changes may be made in the above devices and methods without departing from the scope hereof. For example, the number of turns formed by a spiral winding may be varied. Therefore, the matter contained in the above description and shown in the accompanying drawings should be interpreted as illustrative and not in a limiting sense. The following claims are intended to cover generic and specific features described herein, as well as all statements of the scope of the present method and system, which, as a matter of language, might be said to fall therebetween.

What is claimed is:

1. A magnetic device, comprising:
a magnetic core;
a planar winding wound through the magnetic core and forming at least first and second turns around a center axis; and
a width of the planar winding varying between the first and second turns along a radial direction extending away from the center axis, such that a width of the first turn is smaller than a width of the second turn.

2. The magnetic device of claim 1, the planar winding further forming a third turn around the center axis, a width of the third turn being smaller than the width of the second turn, the second turn being disposed between the first and third turns in the radial direction.

3. The magnetic device of claim 2, the magnetic core comprising:
opposing top and bottom portions; and
opposing inner and outer sidewalls connecting the top and bottom portions;

4. The magnetic device of claim 3, the inner and outer sidewalls sloping in opposite directions.

5. A magnetic device, comprising:
a first semiconductor wafer;
a first spiral winding forming a first plurality of turns and disposed in a first channel of the first semiconductor wafer; and
a magnetic core disposed at least partially in the first channel of the first semiconductor wafer and at least partially surrounding the first plurality of turns.

6. The magnetic device of claim 5, the first channel of the first semiconductor wafer having sloping sidewalls.

7. The magnetic device of claim 6, at least a portion of the magnetic core comprising alternating layers of a magnetic material and an insulating material.

8. The magnetic device of claim 5, further comprising:
a second semiconductor wafer; and
a second winding forming a second plurality of turns and disposed in a second channel of the second semiconductor wafer,
the first and second semiconductor wafers being joined such that the first and second channels are aligned.

9. The magnetic device of claim 8, the magnetic core comprising: a first magnetic core portion formed in the first channel; and a second magnetic core portion formed in the second channel.

10. The magnetic device of claim 9, the first magnetic core portion comprising a first plurality of laminated magnetic layers, the second magnetic core portion comprising a second plurality of laminated magnetic layers, the second plurality of laminated magnetic layers being aligned with the first plurality of laminated magnetic layers.

11. The magnetic device of claim 5, further comprising a second semiconductor wafer, and wherein:
the magnetic core includes:
a first magnetic core portion formed in the first channel of the first semiconductor wafer, and
a second magnetic core portion formed in a second channel of the second semiconductor wafer; and
the first and second semiconductor wafers are joined such that the first and second channels are aligned.

12. The magnetic device of claim 5, a width of the first spiral winding varying between the first plurality of turns such that a width of an edge turn of the first plurality of turns is smaller than a width of a middle turn of the first plurality turns.

13. The magnetic device of claim 5, further comprising an additional magnetic core disposed at least partially in the first channel of the first semiconductor wafer and at least partially surrounding the first plurality of turns.

14. A method for forming an inductor, comprising:
patterning a resist layer on a semiconductor wafer using a mask including compensation features extending angularly from a center portion of the mask;
anistropically etching the semiconductor wafer to form a trench having sloping sidewalls;
disposing a first layer of magnetic material in the trench;
forming a spiral multi-turn winding in the trench on the first layer of magnetic material; and
disposing a second layer of magnetic material on the spiral multi-turn winding.

15. The method of claim 14, the step of anistropically etching comprising etching the semiconductor wafer using a potassium hydroxide solution.

16. The method of claim 15, the step of anistropically etching further comprising agitating the semiconductor wafer in an ultrasonic bath.

17. The method of claim 16, the step of anistropically etching comprising orienting the semiconductor wafer in a container holding the potassium hydroxide solution such that a long edge of the trench is normal to a base of the container.

18. The method of claim 17, the potassium hydroxide solution being at a temperature of about 80 degrees Celsius.

19. A method for forming an inductor, comprising:
patterning a first resist layer on a first semiconductor wafer using a first mask including compensation features extending angularly from a center portion of the first mask;
anistropically etching the first semiconductor wafer to form a first trench having sloping sidewalls;
patterning a second resist layer on a second semiconductor wafer using a second mask including compensation features extending angularly from a center portion of the second mask;
anistropically etching the second semiconductor wafer to form a second trench having sloping sidewalls;
disposing a first layer of magnetic material in the first trench;
disposing a second layer of magnetic material in the second trench;
forming a first spiral multi-turn winding in the first trench on the first layer of magnetic material; and
joining the first and second semiconductor wafers such that the first and second trenches align.

20. The method of claim 19, further comprising forming a second spiral multi-turn winding in the second trench on the second layer of magnetic material, before joining the first and second semiconductor wafers.

21. The method of claim 20, wherein:
the step of anistropically etching the first semiconductor wafer comprises etching the first semiconductor wafer using a first potassium hydroxide solution; and
the step of anistropically etching the second semiconductor wafer comprises etching the second semiconductor wafer using a second potassium hydroxide solution.

22. The method of claim 21, wherein:
the step of anistropically etching the first semiconductor wafer further comprises agitating the first semiconductor wafer in a first ultrasonic bath; and
the step of anistropically etching the second semiconductor wafer further comprises agitating the second semiconductor wafer in a second ultrasonic bath.

23. The method of claim 22, wherein:
the step of anistropically etching the first semiconductor wafer comprises orienting the first semiconductor wafer in a first container holding the first potassium hydroxide solution such that a long edge of the first trench is normal to a base of the first container; and
the step of anistropically etching the second semiconductor wafer comprises orienting the second semiconductor wafer in a second container holding the second potassium hydroxide solution such that a long edge of the second trench is normal to a base of the second container.

24. The method of claim 23, each of the first and second potassium hydroxide solutions being at a temperature of about 80 degrees Celsius.
